(19) United States
(12) Patent Application Publication
(10) Pub. No.: US 2026/0217458 A1
(43) Pub. Date: Jul. 30, 2026

(54) STORAGE RACK, STORED GOODS CARRIER AND METHOD FOR CONTROLLING THE POWER DISTRIBUTION

(71) Applicant: Hänel GmbH & Co. KG, Bad Friedrichshall (DE)

(72) Inventors: Martin Repp, Mudau (DE); Rainer Vogt, Neuenstadt (DE)

(21) Appl. No.: 19/143,510

(22) PCT Filed: Dec. 21, 2023
(86) PCT No.: PCT/EP2023/087393

§ 371 Date: Jun. 26, 2025

(30) Foreign Application Priority Data
Dec. 27, 2022 (DE) 10 2022 134 825.3

(51) Int. Cl. B65G 1/10; H02J 3/1892; H02J 3/32; H02J 105/40; H02J 105/52; H02J 105/54; H05K 5/02

(52) U.S. Cl. CPC B65G 1/10; H02J 3/1892; H02J 3/32; H05K 5/0247; H02J 2105/40; H02J 2105/52; H02J 2105/54

(57) ABSTRACT

The invention relates to a storage rack (100), in particular a vertical lift, comprising a housing (101) in which a plurality of storage locations (102) arranged one above the other for storage goods carriers (103), which can be conveyed by means of an automatic transport device (105), is provided, an operating opening (106) for supplying and removing storage goods (104) and a power supply device (10) for supplying electricity to the storage goods carriers (103). The power supply device (10) has at least one main line (11) running along the storage rack (100), which is configured to carry current for supplying electricity to a plurality of storage goods carriers (103). At least one transmission module (30) is provided which automatically connects or disconnects the storage rack (103) to/from the main line (11) depending on its position.

The invention relates to a storage rack, in particular a vertical lift, for the automatic loading and unloading of storage goods, comprising a housing in which a plurality of storage locations arranged one above the other are provided for storage goods carriers which can be conveyed by means of an automatic transport device, an operating opening for the supply and removal of storage goods and a power supply device for supplying electricity to the storage goods carriers. Furthermore, the invention relates to a storage goods carrier and a computer-implemented process for controlling the distribution of the electric load for such a storage rack.

In automated storage racks of this type, storage goods carriers are stored and retrieved via an operating opening by means of an automatic transport device and delivered to or removed from the storage locations provided in the storage rack. Such storage goods carriers are also known as containers or trays. The transport device is usually arranged between the spaced storage towers of the storage rack and has an extractor for feeding and removing the storage goods carriers. An operator can remove storage goods stored on the storage goods carrier or place them on the storage goods carrier via the operating opening. Such an automatic storage rack is known, for example, from EP 0 722 894 A1 or EP 1 934 120B1.

DE 94 11 922 U1 describes an automatic storage rack that provides a power supply for storage goods carriers. The power supply comprises a plug arranged on the storage rack and a corresponding socket arranged on the storage rack. The plug is brought into contact with the socket when the storage goods carrier is moved into a storage location for the storage goods carrier. The individual sockets are each supplied with electricity via a cable.

The purpose of the invention is to propose a storage rack of a simple design that supplies a large number of storage goods carriers with electricity.

This object is solved by a storage rack with the features according to claim 1, a storage goods carrier according to claim 11 and a process according to claim 13.

Advantageous embodiments are the subject of the dependent claims.

The storage rack according to the invention is characterized in that the power supply device has at least one main line running along the storage rack, which is configured to carry current for supplying electricity to a plurality of storage goods carriers, and in that at least one transmission module is provided, which automatically connects or disconnects the storage goods carrier to/from the main line depending on its position.

As current can be supplied centrally via the main line for supplying electricity to several storage goods carriers, the number of lines required is significantly reduced. This results in a simple and cost-effective design. Furthermore, less installation space is required for the power supply device due to the central routing of the current through the main line. The cross-section of the main line can be larger so that the resistance in the line is lower and heat generation is reduced accordingly.

In general, the term main line refers to an electrically conductive means. In a preferred embodiment, the main line is configured to transmit three-phase current or alternating current. Accordingly, the main line has, for example, several electrically conductive conductors or wires, whereby a phase conductor, a neutral conductor and a protective conductor are provided for the transmission of alternating current. In a further embodiment, the conductors or wires of the main line are configured to transmit three-phase current.

The main line can be made of copper or another conductive material. Furthermore, the main line and its conductors are usually surrounded by a layer of insulation.

In an advantageous embodiment, the transmission module comprises a contacting unit arranged on the storage goods carrier, which is configured to contact the main line directly. This results in a particularly simple design with few components. Furthermore, a large number of connection points can be provided on the main line, allowing flexible assignment. The connection points are preferably each assigned to a storage location. The contacting unit can be configured to transmit three-phase or alternating current.

In another advantageous embodiment, the transmission module comprises a connecting element connected to the main line and a contacting unit arranged on the storage goods carrier connectable to the connecting element.

For example, the connecting element can be a plug socket, comparable to a socket, which is connected to the main line in an electrically conductive manner via an electrically conductive cable, which is also referred to below as the connecting conductor. The contacting unit, on the other hand, can be a plug that engages in the socket or the connecting element in order to establish an electrical contact.

In a further advantageous embodiment, the main line is integrated into a busbar or a flat cable. The busbar and the flat cable are particularly suitable for transmitting high currents. They are also characterized by a simple design.

The main line of the busbar consists of an electrical conductor, for example. The busbar usually has an electrically insulating profile, which can be an extruded profile. The profile is usually rigid and is made of plastic or aluminum. The aluminum profile also has insulation between the main line and the aluminum profile. The profile has a rear side and a front side. Fastening means are arranged on the rear side, which serve to fix the busbar to the storage rack. Recesses can be provided on the front side, which faces a storage location, to allow direct contact with the main line. Furthermore, the recess can have a funnel-shaped insertion attachment. This is particularly advantageous if a plug is provided as a contacting unit, which is arranged on a storage goods carrier and is used for directly contacting the main line. Contacting is made by bringing the plug into engagement with the main line through the recess.

The flat cable, on the other hand, is characterized by the fact that in comparison to a cable it can be configured to be flexible. In this case, the main line can have wires configured to be flexible that are surrounded by flexible insulation. An adapter can be attached to any point on the flat cable to make contact with the main line. The adapter is configured to pierce through the insulation for electrical contacting and to make electrically conductive contact with the main line. The flat cable is usually attached to a side of a wall of the storage rack facing the storage locations by means of surrounding fastening means. Furthermore, the flat cable is particularly suitable for the transmission of three-phase current, as it has five wires arranged next to each other in a simple manner. This can also be used to provide single-phase alternating current or three-phase alternating current.

Both, the busbar and the flat cable, represent a particularly flexible option for the electrification of the storage goods carriers. The arrangement of the recess in a busbar or the attachment of the adapter to a flat cable can be selected as required. Consequently, the storage locations to be supplied with electricity can be freely selected and determined on site when the storage rack is assembled. Furthermore, a large number of recesses can be provided on the busbar, which are arranged at a defined distance from each other.

In an advantageous embodiment of the busbar, it has at least two busbar elements. The busbar elements can each be supplied with electricity via a feed-in element. The individual busbar element comprises a feed-in element that supplies the busbar element with electrical current. For example, the busbar elements can each supply up to five storage goods carriers with electrical current at the same time. The number of storage goods carriers to be supplied with electrical current depends on the cross-section of the main line. With a corresponding cross-section of the main line, it is also possible to supply electricity to up to 10, 20 or 30 storage goods carriers at the same time. This embodiment also has the advantage that the power supply device can be divided into several separate electric circuits. These can be controlled and regulated separately from each other. Furthermore, if one electric circuit fails, only part of the power supply device is affected. This increases safety through additional overload protection devices.

In a further advantageous embodiment comparable to the previously described busbar comprising busbar elements, the flat cable has at least two flat cable elements, whereby the flat cable elements can each be supplied with electricity via a feed-in element. As described above, the flat cable is characterized in particular by its ease of installation. The ease of installation is due, among other things, to the simple and flexible attachment of the adapters. Accordingly, the flat cable is preferably laid over the entire height of the storage rack, in particular the installation shaft. If two flat cable elements are provided, they are laid parallel to each other. Only the adapters are attached at staggered positions across the height of the storage rack.

Advantageously, the contacting unit is a spring contacting unit, a rocking contacting unit or an induction unit. In the case of the spring contacting unit and the rocking contacting unit, a contacting pin can be located in a protected housing when the storage goods carrier is not in the storage location. This is the case, for example, when the storage goods carrier is being transported to the operating opening. In an induction unit, a first coil is located on the main line and a second coil on the storage goods carrier. This enables contactless power transmission.

Advantageously, the power supply device has a central control unit. The central control unit can comprise a controller and is configured to communicate with a warehouse management program. The power supply device can also be supplied with electricity by the central control unit. Such a central control unit is also known as a “wall-mounted box”, for example. The wall-mounted box is configured to supply the power supply device with electricity.

The transmission module can have a regulator unit for regulating the current through the transmission module and a communication unit that can be connected to the central control unit. For example, the regulator unit can reduce or interrupt the current flow. The communication unit enables the regulator unit to be controlled centrally via the control unit. In one possible embodiment, the regulator unit is a controllable circuit breaker.

The power supply device advantageously has a power storage unit, in particular an accumulator. The power storage unit is particularly advantageous if the power supply is interrupted for a longer period of time, for example to supply electricity to other storage goods carriers located in the storage rack as part of a centrally controlled load distribution. The power storage unit can be arranged on the storage rack, for example. Here, the power storage unit is connected to the contacting unit. This is particularly advantageous as the current transmitted by, for example, a spring contacting unit or by means of an induction unit is limited. Accordingly, the provision of a large number of smaller power storage units is particularly advantageous. Alternatively, the power storage unit can be arranged between the main line and the connecting element.

The main line is advantageously arranged in an installation shaft. The installation shaft is arranged on a side of the rack tower facing away from the transport shaft. Usually, only one wall is provided as part of the housing, which is directly or almost directly adjacent to the storage points. Installation space for a power supply device is usually not included. Rather, the installation shaft is arranged additionally and parallel to the wall as a second wall. This doubles the installation shaft, so to speak. The installation shaft not only provides installation space for the power supply device, but also offers mounting options for the power supply device. The installation shaft can also be retrofitted to an existing storage rack. Furthermore, it is also possible to install an installation shaft on an opposite rack tower on a side facing away from the transport shaft. At least one current-conducting connecting element is provided for this purpose, which supplies the power supply device in the installation shaft of the opposite rack tower with electricity. The current-conducting connecting element is laid around the transport shaft on the outside of the housing for this purpose.

A further aspect of the invention relates to a storage goods carrier for the storage rack described above with a contacting unit.

Advantageously, at least one socket for connecting an electrical device or a consumer is provided on the storage goods carrier.

Another aspect of the invention relates to a computer-implemented process for controlling the distribution of electricity for a storage rack described above. The first transmission module comprises a first regulator unit and a first communication unit. The second transmission module has a second regulator unit and a second communication unit. The process has the following steps: Step a) determining the storage rack to be supplied with electricity. Step b) acquiring a maximum electric load that is present on the main line through the storage goods carriers to be supplied with electricity. Step c) transmitting a signal to the communication units of the transmission modules assigned to the specific storage goods carriers for controlling the current by the respective control units.

The process is characterized in that the distribution of electricity can be controlled centrally. A load distribution plan can therefore be created individually for control purposes. For example, storage goods carriers can be supplied with electricity at certain times. Furthermore, the process provides the power supply device with additional preventive protection against an overload of the main line.

In an advantageous embodiment of the process, the central control unit communicates with a storage management program to acquire the electric load, whereby the respective current consumption is stored in the storage management program. The expected electric load applied to the main line can already be taken into account during storage. Accordingly, the storage goods carrier can be assigned to a circuit that has sufficient capacity available so that an overload does not occur. It is also possible to control the timing, for example by storing and supplying electricity to refrigerators in a circuit at different times.

Advantageously, the storage goods carriers to be supplied with electricity have a priority number and in step c) the distribution of electricity is determined depending on the priority number. Here, distribution of electricity can be automated and additionally distributed as required. Furthermore, the priority number specifies a sequence for switching off in order to protect the main line from overloading.

The invention is explained in more detail below with reference to advantageous embodiments, which are shown schematically in the drawing. The combinations of features shown as examples in the embodiments can be supplemented or reduced by further features depending on the respective application, if this can be dispensed with in the respective application. The drawing shows:

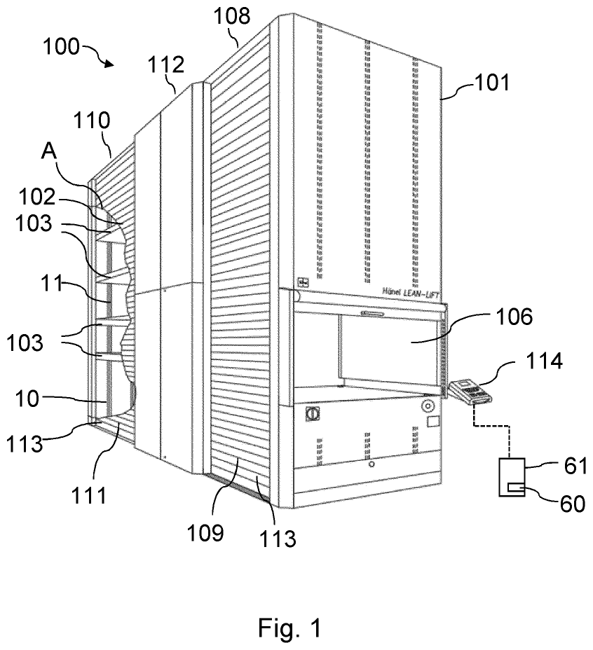

FIG. 1 a perspective view of the storage rack according to the invention in a first embodiment,

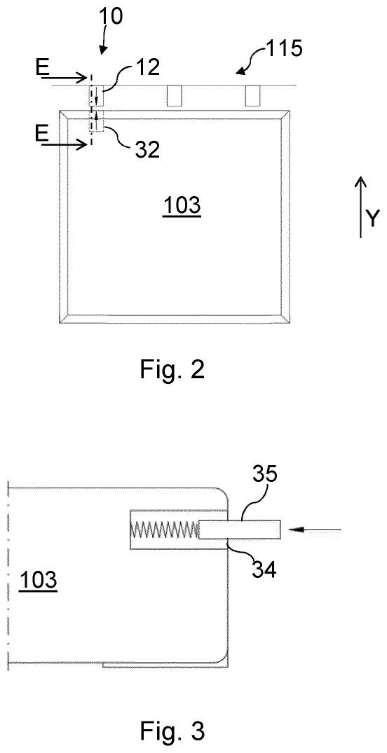

FIG. 2 a schematic top view of a storage goods carrier according to the invention;

FIG. 3 a cross-section along line E-E in FIG. 2 through a spring contacting unit of the storage goods carrier,

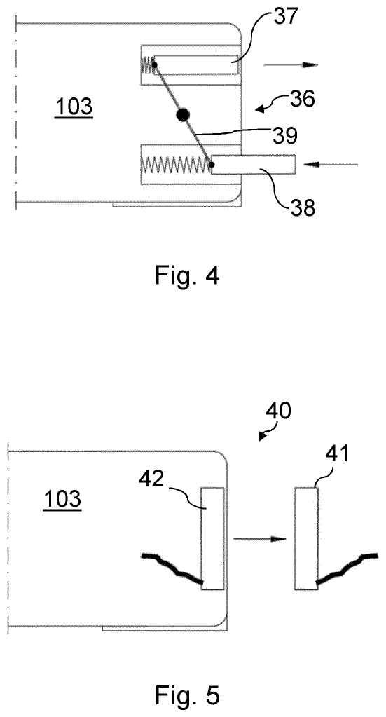

FIG. 4 a cross-section along line E-E in FIG. 2 through a rocking contacting unit,

FIG. 5 a cross-section along line E-E in FIG. 2 through an induction unit,

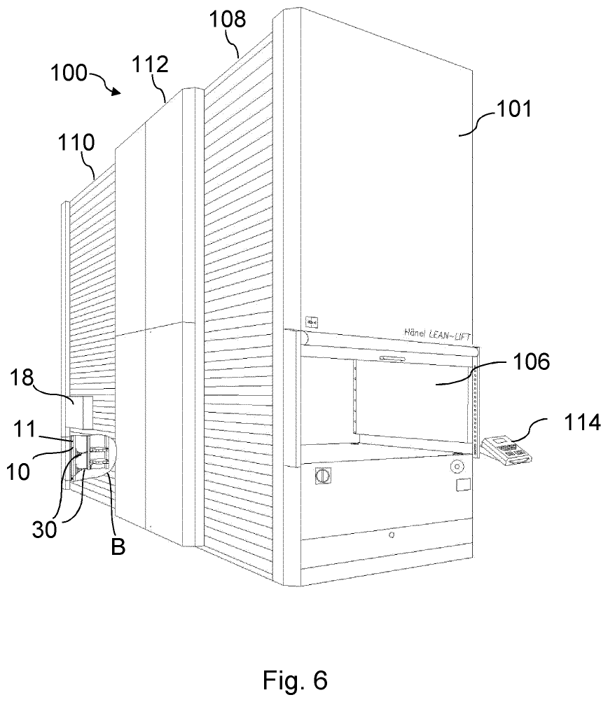

FIG. 6 a perspective view of the storage rack according to the invention in a second embodiment,

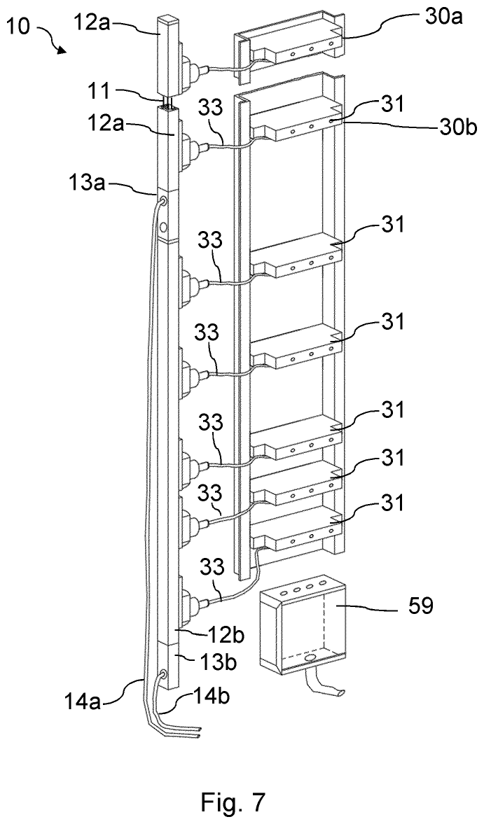

FIG. 7 a perspective view of the power supply device in the second embodiment;

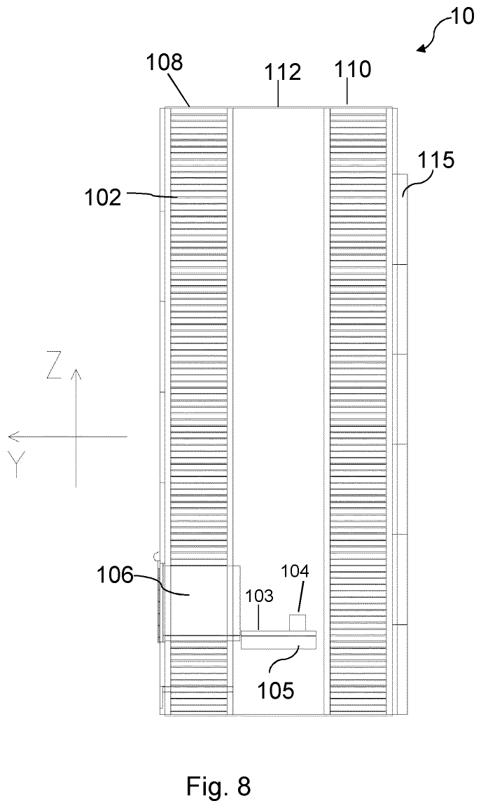

FIG. 8 a cross-section of the storage rack according to the invention in a third embodiment,

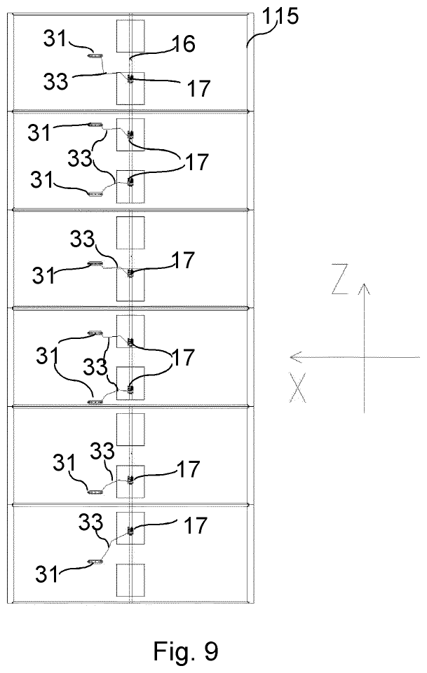

FIG. 9 a top view of an installation shaft with a power supply device in a third embodiment,

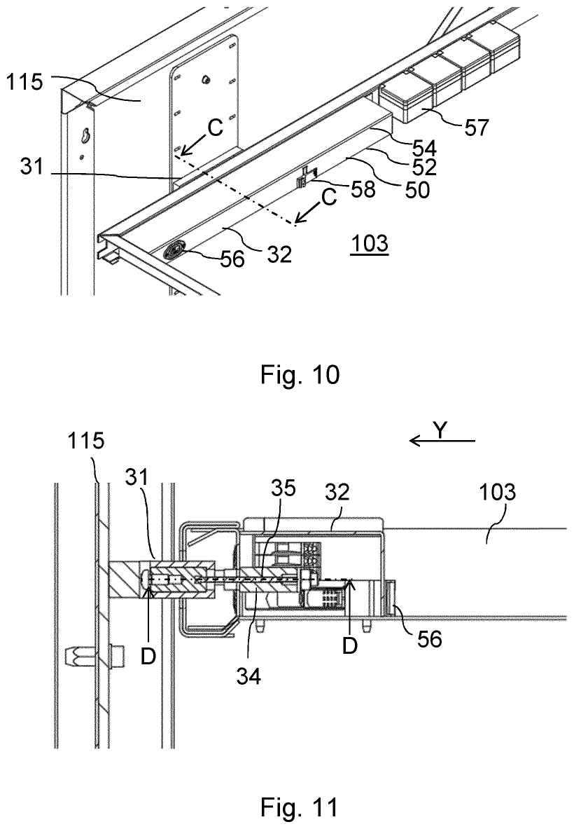

FIG. 10 a detailed perspective view of a storage goods carrier,

FIG. 11 a cross-section along line C-C in FIG. 10 and

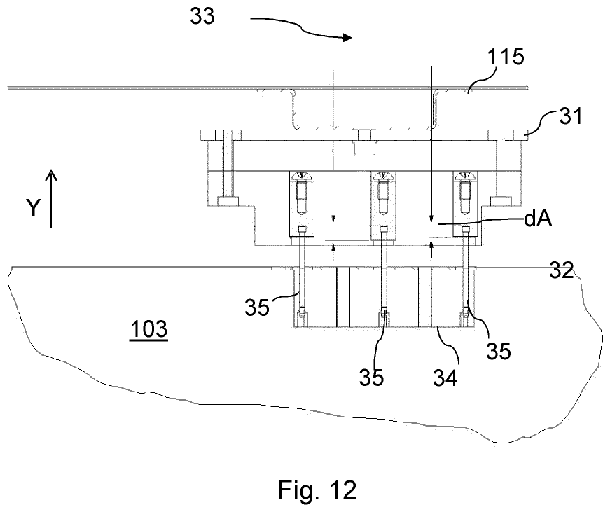

FIG. 12 a cross-section along line D-D in FIG. 11.

FIG. 1 shows the schematic structure of an automatic storage rack 100 configured as a vertical lift. The storage rack 100 has a first rack tower 108, a second rack tower 110 and, arranged between the two rack towers 108, 110, a transport shaft 112 for an automatic transport device 105. The storage rack 100 is enclosed by a housing 101.

In each of the rack towers 108, 110, a plurality of storage locations 102 arranged one above the other are provided for receiving storage goods carriers 103. Storage goods 104, such as small parts, can be stored on the storage goods carriers 103. In order to store the storage goods carriers 103 in the individual storage locations 102, the rack towers 108, 110 have side walls 109, 111 with carrier supports 113 arranged in pairs opposite one another to form a storage location 102.

The side walls 109, 111 made of sheet steel are each welded to uprights, preferably using projection welding technology. The carrier supports 113 are integrated into the respective side walls 109, 111 and pressed into them in a meandering shape. This ensures a comparatively rigid embodiment of the side walls 109, 111. The carrier supports 113 are arranged evenly distributed over the entire side wall 109, 111.

The storage rack 100 has an operating opening 106. The service opening 106 is arranged in the first rack tower 108, so that the side wall 109 laterally delimits the service opening 106. The service opening 106 enables the storage goods 104 to be placed on or removed from the storage goods carriers 103. This procedure is also known as order picking. Further, it is possible to add or remove the storage goods carriers 103 via the operating opening 106.

The storage rack 100 is controlled via a central control unit 60 with a controller 61 and an operating unit 114, which is arranged to the side of the operating opening 106, for example.

An installation shaft 115 is located on a side of the rack tower 110 facing away from the transport shaft 112. A power supply device 10 is arranged in the installation shaft 115, with which the storage goods carrier 103 is supplied with electricity. In the figures, the installation shaft 115 is arranged on a rear side of the storage rack 100, wherein the rear side of the storage rack 100 is a side facing away from the operating opening 106 and the front side of the storage rack 100 is a side surrounding the operating opening 106. However, it is also possible for the installation shaft to be partially arranged on the front side. In this case, the installation shaft 115 on the rear side is connected to the installation shaft 115 on the front side via a bridge that has an electrical connecting element. Comparable to the doubled installation shaft 115, the bridge is arranged on the outside of the housing. The electrical connecting element connects the power supply device 10 on the rear side with the power supply device on the front side.

In FIG. 1, the side wall 111 is shown with a cut-out A, so that the power supply device 10 can be seen in a first embodiment. In this embodiment, the main line 11 can be directly electronically connected by the transmission modules 30. Here, the transmission module 30 only has a contacting unit 32 arranged on the storage goods carrier 103, which is shown in various embodiments in FIG. 2 to FIG. 5. Furthermore, the main line 11 extends along a vertical spatial direction Z over several storage locations 102 and is configured to supply a plurality of storage goods carriers 103 with electricity.

A top view of such a power supply device 10 is shown in FIG. 2, which shows a top view of the storage goods carrier 103. The contacting unit 32 enables current to be drawn directly from the main line 11, which is arranged, for example, in a busbar 12, and transmits the current to an interface for a consumer, which is arranged on the storage goods carrier 103. The interface can be a socket 57, for example. Consequently, the transmission module 30 is configured to be brought into engagement with the main line 11 when the storage goods carrier 103 is stored in a storage location 102.

The busbar 12 can also have an insulating profile that includes recesses on a front side. The recesses can be used to make electrical contact with the main line 11 by means of the transmission module 30. Furthermore, the recess can be provided with a funnel-shaped insertion attachment which serves to facilitate the insertion of a contacting pin 35, 37 of the contacting unit 32.

For this purpose, the contacting unit 32 is arranged in an area of the storage goods carrier 103 facing the installation shaft 115. When the storage goods carrier 103 is moved into the storage location 102 along a horizontal direction Y by means of the extractor to the storage location 102 and reaches its end position, the contacting unit 32 enters into connection with the main line 11 as described above.

The contacting unit 32 can have various embodiments for this purpose, which are shown, for example, in FIG. 3 to FIG. 5. FIG. 3 shows a spring contacting unit 34, FIG. 4 shows a rocking contacting unit 36 and FIG. 5 shows an inductive contacting unit 40.

The spring contacting unit 34 shown in FIG. 3 has a spring contacting pin 35 that is preloaded by means of a spring. The spring contacting pin 35 can engage in a contact opening provided in the connecting element 31 and can establish an electrically conductive contact. Here, a sensor can also be arranged on the storage goods carrier 103 detecting the distance to the installation shaft 115 when the storage goods carrier 103 is stored and releasing an extension of the spring contacting pin 35 with a working stroke dA.

The rocking contacting unit 36 shown in FIG. 4 comprises a contacting pin 37, a pin 38 and a rocker 39. The contacting pin 37 and the pin 38 are preloaded by means of a spring. The pin 38 is connected to the contacting pin 37 via a rocker 39. The rocker 39 is mounted centrally between the pin 38 and the contacting pin 37. If the pin 38 is pressed in, the rocker 39 lifts the contacting pin 37 out by a working stroke dA so that the contacting pin 37 can make contact with the connecting element 31, for example.

FIG. 5 shows the induction contacting unit 40, which comprises two induction coils, namely a primary coil 41 and a secondary coil 42, which are used for contactless energy transmission. The primary coil 41 can serve as a connecting element 31 and the secondary coil 42 can serve as a contacting unit 32.

A further possible embodiment of the storage rack 100 is shown in FIG. 6 and FIG. 7. In this view of the storage rack 100, the side wall 111 is shown with a cut-out B, so that the power supply device 10 can be seen in a second embodiment.

In this embodiment, the power supply device 10 has a main line 11 arranged in a busbar 12 and a plurality of transmission modules 30. For example, a first transmission module 30a and a second transmission module 30b are shown in this figure. The transmission modules 30 each comprise a connecting element 31, which is connected to the main line 11 via a connecting conductor 33, and a contacting unit 32, not shown in FIG. 7, which is arranged on a storage goods carrier 103. The contacting units 32 of this embodiment are comparable to the contacting units 32 described above. However, the contacting units 32 of this embodiment are configured to make electrical contact with the connecting elements 31.

The connecting conductor 33 is, for example, a power cable made of copper that comprises a cable lug with an eye at one end, which is connected to the connecting element 31 in an electrically conductive manner by means of a screw. The other end can, for example, be connected to a flat cable 16 via an adapter 17 described below or to the busbar 12 or the main line 11 by means of another connection.

Further, in the embodiment shown, the busbar 12 advantageously has a plurality of busbar elements 12a, 12b. The busbar elements 12a, 12b each comprise a feed-in element 13a, 13b, which is supplied with electricity via a supply line 14a, 14b, which in turn are connected to a so-called wall-mounted box 18. A single busbar element 12a, 12b can supply up to five storage goods carriers 103 with electricity at the same time. However, the maximum number of storage goods carriers 103 that can be supplied with electricity depends on the busbar or flat cable used with a corresponding wall-mounted box 18. In particular, the embodiment of the cross-section of the current-conducting main line 11 limits the maximum number of storage goods carriers 103 to be supplied with electricity. It is therefore also conceivable to provide a main line 11 with a larger cross-section for supplying electricity to 10, 20 or more storage goods carriers 103. The busbar 12 as a whole can be scaled to any length by dividing it into several busbar elements 12a, 12b. In addition, each busbar element 12a, 12b can be protected against overcurrent and/or residual current via a circuit breaker 59.

FIG. 9 shows a third embodiment of the storage rack 100 with a power supply device 10, which essentially differs from the second embodiment in that a flat cable 16 comprises the main line 11 instead of the busbar 12. For this purpose, the flat cable 16 is additionally provided with an adapter 17, which is configured to make contact with the main line 11 and thus establishes an electrical connection between a connecting conductor 33 and the main line 11. For contacting, the adapter 17 pierces through the insulation of the flat cable 16. The adapter 17 can be attached flexibly over the entire main line 11 in an advantageous manner.

Comparable to the second embodiment, the transmission module 30 thus comprises a contacting unit 32 not shown in FIG. 9 and, as previously described with reference to the second embodiment, a connecting element 31 which can be electrically connected to the contacting unit 32.

In all embodiments, the power supply device 10 and in particular the main line 11 of the embodiments described above are configured to transmit alternating current or three-phase current and/or direct current. For the transmission of alternating current, the main line 11 has three conductors, namely a phase conductor, a protective conductor and a neutral conductor. The phase conductor is the current-carrying conductor and can provide a star voltage of between 110 V and 277 V, depending on the mains voltage and country of use.

For the transmission of three-phase current, the main line 11 has five conductors, namely three phase conductors, a protective conductor and a neutral conductor. The three phase conductors are the current-carrying conductors and can provide between 208 V and 480 V depending on the mains voltage and country of use.

The main line 11 has an additional line for transmitting direct current. However, the transmission of direct current is usually only used to supply additional current to an inverter without an additional rectifier and forms a so-called intermediate circuit. In this respect, the transmission of direct current via the main line 11 is provided as an additional electric circuit alongside the electric circuit for transmitting the afore-mentioned alternating current or three-phase current.

The current-carrying conductors are configured to conduct a current of between 25 A and 63 A, for example. The wall-mounted box 18 uses a circuit breaker to monitor the fault current, the overload current and the short-circuit current.

Furthermore, the transmission module 30 of all embodiments comprises a regulator unit 50, a communication unit 52 and a power storage unit 54, which can be arranged on the connecting element 31 or the contacting unit 32.

The regulator unit 50 is configured to reduce or interrupt the current. The communication unit 52 is configured to communicate with a central control unit 60 and/or the wall-mounted box 18. The power storage unit 54 can be an accumulator and preferably an accumulator with a bi-directional inverter, which is configured to store electricity and to feed it back again.

The contacting unit 32 comprises, for example, an appliance socket 56, such as a cold appliance socket, a socket 57, such as an earthed socket, and a circuit breaker 58 for protecting the terminal devices that receive electricity via the aforementioned sockets 56, 57, in order to provide electricity to terminal devices that are to be supplied with electricity on the storage goods carrier 13.

For electrical contacting of the contacting unit 32 with the connecting unit 31 or directly with the main line 11, the contacting unit 32 can comprise, for example, a spring contacting pin 35, a rocking contacting unit 36 or an inductive contacting unit 40, which are described in more detail below.

The central control unit 60 is connected to the controller 61 and, as described above, controls the automatic transport device 105 for storing and retrieving the storage goods carriers 103. The lift control software and the warehouse management program are stored in the control unit 60.

The control unit 60 can be configured to additionally communicate with a communication unit 52, which is provided on the storage goods carrier 103. The communication can take place via a cable or via wireless data transmission and comprises information as to whether the regulator unit 50 releases, blocks or reduces current for supplying electricity to the storage goods carrier 103.

Preferably, the control is used to ensure that the power supply device 10 is not overloaded if too many storage units 103 are to be supplied with electricity. In order for the load to be distributed, load management is enabled via the regulator 50 and the central control unit 60.

For example, the storage goods carriers 103 can thus be alternately supplied with electricity. The power storage units 52 can also bridge the time between the time ranges in which power is available.

Furthermore, a priority number can be stored in the warehouse management pro-gram. For example, a storage goods carrier 103 with a terminal device whose power supply may only be interrupted for a short time is assigned a high priority number. Accordingly, the central control unit 60 can take this priority number into account when distributing power and only interrupt the power supply to the corresponding storage goods carrier 103 for a short time.

The proposed storage rack 100 is characterized above all by the fact that the centralized and decentralized control and routing of electricity through the main line 11 requires fewer copper conductors and thus enables a resource-saving and simpler design. Centralized control is to be understood as control via the wall-mounted box 18. Decentralized control means that the storage goods carriers each have a control unit.

Furthermore, a plurality of storage locations 102 can be supplied with electricity at the same time, so that a storage rack 100 is created in which a plurality of storage locations 102 can be constructed in a modular and flexible manner. The proposed power supply device 10 can supply a plurality of storage locations 102 with electricity. Since the storage locations 102 are formed by the carrier supports, which are arranged at a relatively small distance from one another, a plurality of storage locations 102 can thus also be provided, which can be supplied with electricity. A significantly more flexible storage rack 100 is thus created, as the selection of storage locations 102 can be freely and flexibly selected.

In all the embodiments of the invention described above, the electrical connection and decoupling of the storage goods carrier (103) takes place when it is fed into the storage location (102) or when it is removed from the storage location (102), which takes place by the extractor of the transport device (105).

### LIST OF REFERENCE SYMBOLS

10 Power supply device
11 Main line
12 Busbar
12a Busbar element
13a Feed-in element
12b Busbar element
13b Feed-in element
14a Supply line
14b Supply line
16 Flat cable
17 Adapter
18 Wallbox
30 Transmission module
30a First transmission module
30b Second transmission module
31 Connecting element
32 Contacting unit
33 Connecting conductor
34 Spring contacting unit
35 Spring contacting pin
36 Rocking contacting unit
37 Contacting pin
38 Pin
39 Rocker
40 Induction unit
41 Primary coil
42 Secondary coil
50 Controller unit
52 Communication unit
54 Power storage unit
56 Appliance socket
57 Socket
58 Circuit breaker
59 Circuit breaker
60 Central control unit
61 Controller
100 Storage rack
101 Housing
102 Storage location
103 Storage goods carrier
104 Storage goods
105 Transport device
106 Operating opening
108 First rack tower
109 Side wall
110 Second rack tower
111 Side wall
112 Transport shaft
113 Carrier supports
114 Operating unit
115 Installation shaft
dA Working stroke

1. A storage rack in particular a vertical lift, comprising a plurality of storage goods carriers, a housing in which a plurality of storage locations arranged one above the other for storage goods carriers, which can be conveyed by means of an automatic transport device is provided,
an operating opening for supplying and removing storage goods, and a power supply device for supplying electricity to the storage goods carriers,
wherein the power supply device has at least one main line running along the storage rack and is configured to carry current for supplying electricity to the plurality of storage goods carriers, and
wherein a plurality of transmission module modules are provided which automatically connects or disconnects the storage goods carrier to/from the main line depending on its position,
wherein the transmission modules each comprise a contacting unit arranged on the storage goods carrier, which is configured to contact the main line directly, or the transmission modules each comprise a connecting element connected to the main line and a contacting unit arranged on the storage goods carrier, which can be connected to the connecting element;
wherein the power supply device has a central control unit,
wherein the transmission modules each have a regulator unit for regulating the current through the transmission module and a communication unit which can be connected to the central control unit
wherein the contacting unit is a spring contacting unit or a rocking contacting unit, and
wherein the contact unit for supplying power to terminal devices that are to be supplied with power on the storage goods carrier has at least one socket and a circuit breaker for protecting the terminal devices that draw power via the at least one socket.

2. (canceled)

3. (canceled)

4. The storage rack according to claim 1, wherein the main line is integrated in a busbar or in a flat cable.

5. The storage rack according to claim 4, wherein the busbar has at least two busbar elements, wherein the busbar elements can each be supplied with electricity via a feed-in element, or in that the flat cable has at least two flat cable elements, wherein the flat cable elements can each be supplied with electricity via a feed-in element.

6. (canceled)

7. (canceled)

8. (canceled)

9. The storage rack according to claim 4, wherein the power supply device comprises a power storage unit.

10. The storage rack according to claim 4, wherein the main line is arranged in an installation shaft.

11. (canceled)

12. The storage goods carrier according to claim 4, wherein at least one socket for connecting an electrical device or a consumer is provided on the storage goods carrier.

13. A computer-implemented process for controlling distribution of electricity for a storage rack according to claim 1, wherein the first transmission module comprises a first regulator unit and a first communication unit. wherein the second transmission module comprises a second regulator unit and a second communication unit. and wherein the process comprises the following steps:
a. determining the storage goods carriers to be supplied with electricity;
b. acquiring a maximum electric load that is applied to the main line by the storage goods carriers to be supplied with electricity;
c. transmitting a signal to the communication units of the transmission modules assigned to the particular storage goods carriers for controlling the current through the respective control units. wherein the storage goods carriers (103) to be supplied with electricity have a priority number and distribution of electricity is determined depending on the priority number.

14. The computer-implemented process according to claim 13, characterized in that the central control unit communicates with a storage management program to acquire the maximum electric load, the current consumption quantity being stored in the storage management program.

15. (canceled)

16. (canceled)
